(19) United States
(12) Patent Application Publication
(10) Pub. No.: US 2007/0210415 A1
(43) Pub. Date: Sep. 13, 2007

(54) Anti-fuse and programming method of the same

(76) Inventor: Ping-Chang Wu, Jhudong Township (TW)

Correspondence Address: J.C. Patents, Inc.;Suite 250, 4 Venture, Irvine, CA, 92618, US

(21) Appl. No.: 11/370,485

(22) Filed: Mar. 7, 2006

(51) Int. Cl. H01L 29/00

(52) U.S. Cl. 257/530

(57) ABSTRACT

The invention is directed to an anti-fuse comprised of a substrate, a gate electrode, and a gate dielectric layer. The gate electrode is located on the substrate. The gate dielectric layer is placed between the gate electrode and the substrate. The method of programming the anti-fuse is accomplished by applying a bias voltage to between the gate electrode and the substrate to break down the gate dielectric layer and convert the resistance between the gate electrode and the substrate to be smaller than that before the breakdown of the gate dielectric layer happens. By using the anti-fuse, area occupied by the anti-fuse in the chip is decreased and the programming of the anti-fuse can be done after the chip is packed.

### BACKGROUND OF THE INVENTION

1. Field of Invention

The present invention relates to a semiconductor device and a programming method of the same. More particularly, the present invention relates to an anti-fuse and a programming method of the same.

2. Description of Related Art

With the decreasing of the size of the chip, the semiconductor devices are affected by the defects within the silicon crystal or other impurities within the chip. To solve the problem mentioned above, some fuse circuits are commonly formed in the semiconductor device. When the problem circuit is founded during the testing process, the problem circuit can be turned off by fusing the fuse.

Generally, the fuse is formed from polysilicon or metal material. Furthermore, the common way to blow the fuse to form the broken circuit is to use laser beam to burn the fuse. This kind of fuse is the so-called laser fuse. However, being limited to the wavelength of the laser, the surface area of the laser fuse should be large enough to be accurately attacked by the laser beam. Moreover, after the chip is packed, the programming process for fusing the fuse cannot be done by using the laser beam. Hence, the application of the laser fuse is limited.

### SUMMARY OF THE INVENTION

Accordingly, at least one objective of the present invention is to provide an anti-fuse, which is a kind of electrical fuse, capable of decreasing the area for equipping the fuse in the chip.

At least another objective of the present invention is to provide a method for programming an anti-fuse capable of blowing the fuse after the chip is packed.

To achieve these and other advantages and in accordance with the purpose of the invention, as embodied and broadly described herein, the invention provides an anti-fuse structure. The anti-fuse structure comprises a substrate, a gate electrode and a gate dielectric layer. The gate electrode is located on the substrate and the gate dielectric layer is located between the gate electrode and the substrate.

The present invention also provides a method for programming an anti-fuse, wherein the anti-fuse comprises a gate electrode located on a substrate and a gate dielectric layer located between the substrate and the gate electrode, and there is a first resistance between the gate electrode and the substrate. The method comprises a step of applying a bias between the gate electrode and the substrate so as to break down the gate dielectric layer and, meanwhile, converting the first resistance into a second resistance, wherein the second resistance smaller than the first resistance.

According to one embodiment of the present invention, the anti-fuse further comprising a source region and the drain region located in the substrate adjacent to both sides of the gate electrode respectively.

According to one embodiment of the present invention, the bias is applied between the gate electrode and the source region or between the gate electrode and the drain region.

According to one embodiment of the present invention, the bias is applied both between the gate electrode and the source region and between the gate electrode and the drain region.

According to one embodiment of the present invention, the substrate is made of silicon.

According to one embodiment of the present invention, the substrate has N conductive type dopants or P conductive type dopants.

According to one embodiment of the present invention, the gate electrode is made of doped polysilicon.

According to one embodiment of the present invention, the gate dielectric layer is made of silicon oxide or silicon nitride.

In the present invention, a bias is applied on the anti-fuse to break down the gate dielectric layer between the gate electrode and the substrate of the anti-fuse so as to accomplish the programming of the anti-fuse. Therefore, the minimum size of the anti-fuse is not limited to the wavelength of the laser beam as it limits the size of the laser fuse size. Hence, the anti-fuse does not occupy too much area of the chip. Additionally, since the anti-fuse is programmed by applying the bias thereon, the anti-fuse can be programmed after the chip is packed.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view schematically showing an anti-fuse according to a preferred embodiment of the invention.

FIG. 2 is a cross-sectional view schematically showing another anti-fuse according to a preferred embodiment of the invention.

FIG. 3 is a top view schematically showing several regions equipping with fuses of a semiconductor wafer.

### DESCRIPTION OF THE PREFERRED EMBODIMENTS

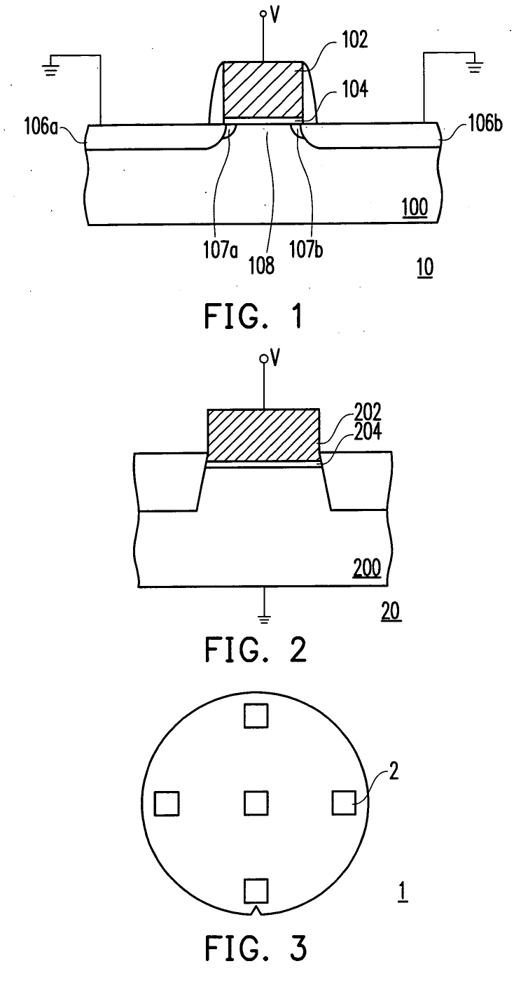

FIG. 1 is a cross-sectional view schematically showing an anti-fuse according to a preferred embodiment of the invention. As shown in FIG. 1, an anti-fuse, such as a metal-oxide-semiconductor transistor, is comprised of a substrate 100, a gate electrode 102, gate dielectric layer 104, a source region 106a and a drain region 106b. The substrate 100 can be, for example, formed from silicon. The gate electrode 102 is located on the substrate and the gate electrode 102 can be, for example, made of doped polysilicon. The gate dielectric layer 104 is located between the gate electrode 102 and the substrate 100 and the gate dielectric layer 104 can be, for example but not limited to, made of silicon oxide or silicon nitride. The source region 106a and the drain region 106b are located in the substrate 100 adjacent to both sides of the gate electrode 102 respectively. Furthermore, the source region 106a and the drain region 106b are both heavily doped regions. Generally, the dopant concentration of the heavily doped region is larger than that of the substrate 100 and the substrate 100 can be, for example, an N type well or a P type well. Additionally, a region under the gate dielectric layer 104 and between the source region 106a and the drain region 106b is defined as a channel region 108.

Moreover, in the present embodiment, the anti-fuse 10 further comprises a source extension region 107a located between the source region 106a and the channel region 108 and a drain extension region 107b located between the drain region 106b and the channel region 108. The source extension region 107a and the drain extension region 107b can be, for example, lightly doped regions. The dopant concentration of the lightly doped region is smaller than that of the heavily doped region. Therefore, the dopant concentrations of the source extension region 107a and the drain extension region 107b are smaller than those of the source region 106a and the drain region 106b. Nevertheless, the present invention is not limited to the above description. In another embodiment, the dopant concentrations of the source region, the drain region, the source extension region and the drain extension region are the same.

When a bias is properly applied onto the anti-fuse, the gate dielectric layer 104 is broken down to generate several current paths therein and the current paths possess different resistances. The current paths are generated between the gate electrode 102, the channel region 108, the source region 106a, the drain region 106b, the source extension region 107a and the drain extension region 107b. It should be noticed that the current path between the gate electrode 102 and the source region 106a and the drain region 106b possesses the minimum resistance but the current path between the gate electrode 102 and the channel region 108 possesses the relatively large resistance. Noticeably, before the gate dielectric layer is broken down, the resistance between the gate electrode 102 and the substrate 100 within the anti-fuse 10 is larger than the resistances of the aforementioned current paths.

As the electrical properties described above, the programming method of the anti-fuse 10 comprises a step of applying a bias between the gate electrode 102 and the substrate 100 to break down the gate dielectric layer 104. Meanwhile, the resistance between the gate electrode 102 and the substrate 100 after the gate dielectric layer 104 is broken down is smaller than that before the gate dielectric layer 104 is not broken down. As for generating current paths between the gate electrode 102 and the source region 106a and the drain region 106b in one embodiment, the bias can be, for example, accomplished by applying a voltage V onto the gate electrode 102 and grounding both of the source region 106a and the drain region 106b so as to break down the gate dielectric layer 104 (as shown in FIG. 1) In another embodiment, the bias can be, for example, accomplished by applying a voltage V onto the gate electrode and grounding one of the source region and the drain region. In the other embodiment, the bias can be, for example, accomplished by applying a voltage V onto both of the source region and the drain region and grounding the gate electrode. Furthermore, the way to apply bias on the anti-fuse in present invention is not limited to the aforementioned description and there are still many ways to apply a bias on the anti-fuse to accomplish the same function according to the present invention.

Specially, as described above, by using the current paths between the gate electrode and the substrate after the gate dielectric layer is broken down, the anti-fuse can be in a form as shown in FIG. 2. FIG. 2 is a cross-sectional view schematically showing another anti-fuse according to a preferred embodiment of the invention. As shown in FIG. 2, the anti-fuse 20 is comprised of a susbtrate 200, a gate electrode 202 and a gate dielectric layer 204. The materials and the electrical properties of the substrate 200, the gate electrode 202 and the gate dielectric layer 204 are as same as those of the substrate 100, the gate electrode 102 and the gate dielectric layer 104. Referring to FIG. 2, the programming method of the anti-fuse comprises a step of applying a bias between the gate electrode 202 and the substrate 200 to break down the gate dielectric layer 204 so that the resistance between the gate electrode 202 and the substrate 200 is smaller than it is before. However, the way to apply the bias on the anti-fuse of the present invention is not limited to the description mentioned above.

FIG. 3 is a top view schematically showing several regions equipping with fuses of a semiconductor wafer. Table 1 shows testing results of the anti-fuse on the semiconductor wafer shown in FIG. 3.

As shown in FIG. 3 together with Table 1, before the anti-fuses 10 in the wafer 1 are not blown, the resistances between the gate electrode 102 and the substrate 100 of each anti-fuse 10 in five testing regions 2 including the central region, the right-hand-side region of the central region, the left-hand-side region of the central region, the upper region of the central region and the lower region of the central region of the wafer 1 are sampled. Then, after the anti-fuses 10 are blown by applying biases between the gate electrode 102 and the substrate 100 thereof, the resistances between the gate electrode 102 and the substrate 100 of each anti-fuse 10 in the aforementioned five testing regions 2 are measured as well. As shown in Table 1, the resistance before the anti-fuse is blown is about 10⁷ times of the resistance after the anti-fuse is blown. Moreover, the resistances in every sampling regions 2 are similar to each other and the differences of the resistances between every sampling regions 2 are smaller than 5 ohms. Therefore, the anti-fuse according to the present invention can be massively produced and possesses a uniform quality.

TABLE 1

| | Sampling regions | | | | |
|---|---|---|---|---|---|
| Condition | right | central | left | lower | Upper |
| Blown | 26.3 | 27.2 | 28.0 | 31.6 | 26.8 |
| (connection) | | | | | |
| Un-blown | 1.19E+8 | 1.22E+8 | 1.26E+8 | 1.26E+8 | 1.26E+8 |
| (dis- | | | | | |
| connection) | | | | | |

Comparing to the conventional laser fuse, the anti-fuse of the present invention is based on the breaking down the gate dielectric layer by applying a bias on the anti-fuse to accomplish the programming of the anti-fuse. Therefore, the line width is not limited to the laser wave length or the diameter of the laser spot. Hence, the size of the anti-fuse is relatively small and does not occupy too much area of the chip. Additionally, the programming of the anti-fuse is carried out by applying the bias on the anti-fuse. Accordingly, the anti-fuse in the chip can be programmed after the chip is packed. Moreover, the anti-fuse of the present invention can be integrated with the formation of the metal-oxide-semiconductor transistor without performing additional manufacturing process. Therefore, the cost is decreased.

It will be apparent to those skilled in the art that various modifications and variations can be made to the structure of the present invention without departing from 15 the scope or spirit of the invention. In view of the foregoing descriptions, it is intended that the present invention covers modifications and variations of this invention if they fall within the scope of the following claims and their equivalents.

What is claimed is:

1. An anti-fuse structure, comprising:
a substrate;
a gate electrode located on the substrate; and
a gate dielectric layer located between the gate electrode and the substrate.

2. The anti-fuse of claim 1 further comprising a source region and the drain region located in the substrate adjacent to both sides of the gate electrode respectively.

3. The anti-fuse of claim 1, wherein the substrate is made of silicon.

4. The anti-fuse of claim 1, wherein the substrate has N conductive type dopants or P conductive type dopants.

5. The anti-fuse of claim 1, wherein the gate electrode is made of doped polysilicon.

6. The anti-fuse of claim 1, wherein the gate dielectric layer is made of silicon oxide or silicon nitride.

7. A method for programming an anti-fuse, wherein the anti-fuse comprises a gate electrode located on a substrate and a gate dielectric layer located between the substrate and the gate electrode, and there is a first resistance between the gate electrode and the substrate, the method comprising:
applying a bias between the gate electrode and the substrate so as to break down the gate dielectric layer and, meanwhile, converting the first resistance into a second resistance, wherein the second resistance smaller than the first resistance.

8. The method of claim 7, wherein the anti-fuse comprises a source region and a drain region located in the substrate adjacent to both sides of the gate electrode and the bias is applied between the gate electrode and the source region or between the gate electrode and the drain region.

9. The method of claim 7, wherein the anti-fuse comprises a source region and a drain region located in the substrate adjacent to both sides of the gate electrode and the bias is applied both between the gate electrode and the source region and between the gate electrode and the drain region.

10. The method of claim 7, wherein the substrate is made of silicon.

11. The method of claim 7, wherein the substrate has N conductive type dopants or P conductive type dopants.

12. The method of claim 7, wherein the gate electrode is made of doped polysilicon.

13. The method of claim 7, wherein the gate dielectric layer is made of silicon oxide or silicon nitride.
